(19) United States
(12) Patent Application Publication
(10) Pub. No.: US 2012/0235708 A1
(43) Pub. Date: Sep. 20, 2012

(54) Method and System for High Speed Differential Synchronous Sense Amplifier

(76) Inventor: Mark Slamowitz, Chandler, AZ (US)

(21) Appl. No.: 13/049,301

(22) Filed: Mar. 16, 2011

(51) Int. Cl. H03F 3/45

(52) U.S. Cl. 327/53

(57) ABSTRACT

A sense amplifier may be operable to form a current-mirror reference using a first PMOS transistor and a NMOS transistor. Currents at a first internal terminal and a second internal terminal may be generated based on the current-mirror reference. Voltage signals at the first internal terminal and the second internal terminal may be generated based on received differential input signals and the currents at the first internal terminal and the second internal terminal. The sense amplifier may limit voltage excursions of the voltage signals at the first internal terminal and/or of the second internal terminal using a pair of cross coupled PMOS transistors, respectively. Voltage signals at a third internal terminal and a fourth internal terminal may be generated based on voltage signals at the first internal terminal and the second internal terminal. An output signal may be generated based on the voltage signal at the fourth internal terminal.

### CROSS-REFERENCE TO RELATED APPLICATIONS/INCORPORATION BY REFERENCE

[Not applicable]

### FIELD OF THE INVENTION

Certain embodiments of the invention relate to amplifier circuits. More specifically, certain embodiments of the invention relate to a method and system for high speed differential synchronous sense amplifier.

### BACKGROUND OF THE INVENTION

A sense amplifier is a circuit that is utilized in the design of memory chips such as static random access memory (SRAM) chips. In a differential memory structure, the memory may have its bitlines pre-charged to a high voltage prior to a selection of a single memory cell. Once a memory cell is read-selected, a current path to ground is formed on one of the bitlines of a bitline pair and a voltage on that bitline may deviate from the original high voltage by discharging the bitline capacitance toward ground. Due to large arrays of memory cells, the resulting signal, in the event of a read operation, may have a very small voltage swing between the bitlines. To compensate for this small voltage swing, a sense amplifier may be used to amplify input bitline swing of small voltage to full voltage levels for representing logic levels. An operation of the sense amplifier may consist of a pre-charge phase and an evaluation phase.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for high speed differential synchronous sense amplifier, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary memory architecture that is operable to provide high speed differential synchronous sense amplifier during read operation, in accordance with an embodiment of the invention.

FIG. 2 is a schematic diagram illustrating an exemplary high speed differential synchronous sense amplifier, in accordance with an embodiment of the invention.

FIG. 3 is a timing diagram illustrating an exemplary read-low operation of a high speed differential synchronous sense amplifier, in accordance with an embodiment of the invention.

FIG. 4 is a timing diagram illustrating an exemplary read-high operation of a high speed differential synchronous sense amplifier, in accordance with an embodiment of the invention.

FIG. 5 is a flow chart illustrating exemplary steps for a high speed differential synchronous sense amplifier, in accordance with an embodiment of the invention.

### DETAILED DESCRIPTION OF THE INVENTION

Certain embodiments of the invention can be found in a method and system for high speed differential synchronous sense amplifier. In various embodiments of the invention, a sense amplifier may comprise a first internal terminal, a second internal terminal, a third internal terminal, a fourth internal terminal, a first PMOS transistor, a second PMOS transistor, a third PMOS transistor and a NMOS transistor. When the sense amplifier is turned on and receives differential input signals at a pair of differential input terminals, the sense amplifier may be operable to form a first current-mirror reference using the first PMOS transistor and the NMOS transistor. In this regard, a gate terminal of the first PMOS transistor may be coupled to a drain terminal of the first PMOS transistor. A drain terminal of the NMOS transistor may be coupled to the drain terminal of the first PMOS transistor. A gate terminal of the NMOS transistor may receive a sense enable signal that may enable the turning on of the sense amplifier. A current at the first internal terminal and a current at the second internal terminal may be generated by the sense amplifier based on the first current-mirror reference.

A voltage signal at the first internal terminal and a voltage signal at the second internal terminal may be generated by the sense amplifier based on the received differential input signals, the current at the first internal terminal and the current at the second internal terminal. The sense amplifier may be operable to limit voltage excursions of the voltage signal at the first internal terminal and/or of the voltage signal at the second internal terminal using the second PMOS transistor and the third PMOS transistor, respectively. In this regard, the second PMOS transistor and the third PMOS transistor may be cross coupled. A gate terminal of the second PMOS transistor may be coupled to the second internal terminal. A drain terminal of the second PMOS transistor may be coupled to the first internal terminal. A gate terminal of the third PMOS transistor may be coupled to the first internal terminal. A drain terminal of the third PMOS transistor may be coupled to the second internal terminal.

A voltage signal at the third internal terminal and a voltage signal at the fourth internal terminal may be generated by the sense amplifier based on the voltage signal at the first internal terminal, a current at the third internal terminal, the voltage signal at the second internal terminal and a current at the fourth internal terminal. In this regard, the current at the third internal terminal is a second current-mirror reference and the current at the fourth internal terminal may be generated based on the second current-mirror reference.

The sense amplifier may be operable to generate an output signal at an output terminal of the sense amplifier based on the voltage signal at the fourth internal terminal. When the sense amplifier is turned off via the sense enable signal, the sense amplifier may be operable to hold the output signal at the output terminal at a current voltage level using an inverter and a first tri-state inverter. In this regard, the inverter and the first tri-state inverter may be back-to-back connected and the output terminal may be coupled to an input terminal of the inverter. The first tri-state inverter may be controlled by the sense amplifier using the sense enable signal.

In an exemplary embodiment of the invention, the sense amplifier may be operable to generate the output signal at the output terminal of the sense amplifier via a second tri-state inverter between the fourth internal terminal and the output terminal. In this regard, the voltage signal at the fourth internal terminal is an input signal of the second tri-state inverter. The second tri-state inverter may be controlled by the sense amplifier using the sense enable signal.

When the sense amplifier is turned off via the sense enable signal, the first internal terminal may be pre-charged to a high voltage level by the sense amplifier. The second internal terminal may also be pre-charged to a high voltage level. The third internal terminal may be pre-charged to a low voltage level by the sense amplifier. The fourth internal terminal may also be pre-charged to a low voltage level.

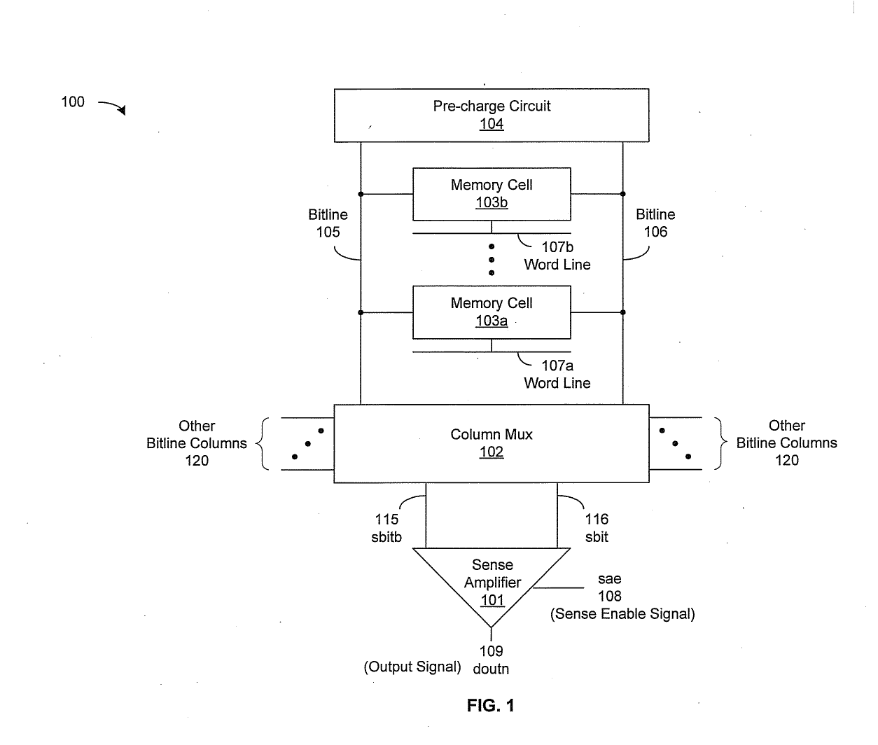

FIG. 1 is a block diagram illustrating an exemplary memory architecture that is operable to provide high speed differential synchronous sense amplifier during read operation, in accordance with an embodiment of the invention. Referring to FIG. 1, there is shown a memory architecture 100 during read operation. The memory architecture 100 may comprise a sense amplifier 101, a column mux 102, a pre-charge circuit 104 and a plurality of memory cells, of which memory cells 103a-103b are illustrated.

Each of the memory cells such as the memory cell 103a may comprise suitable logic, circuitry, interfaces and/or code that may be operable to store a memory bit. The memory cell 103a may have two stable states which are used to denote logic 0 and logic 1. Access to the memory cell 103a is enabled by a word line such as a word line 107a. The word line 107a may control whether the memory cell 103a connects to a pair of bitlines 105, 106 and puts data on the bitlines 105, 106.

The pre-charge circuit 104 may comprise suitable logic, circuitry, interfaces and/or code that may be operable to pre-charge the bitlines 105, 106 to a high voltage level representing logic 1 prior to a selection of a memory cell such as the memory cell 103a.

The column mux 102 may comprise suitable logic, circuitry, interfaces and/or code that may be operable to merge or multiplex a plurality of bitline columns such as the bitline pair 105, 106 and other bitline columns 120 into a combined bitline pair at terminals sbit 116 and sbitb 115 for the sense amplifier 101.

The sense amplifier 101 may comprise suitable logic, circuitry, interfaces and/or code that may be operable to amplify input bitline swing or deviation of small voltage between the terminals sbit 116, sbitb 115 to full voltage levels for representing logic levels at an output terminal doutn 109. For example, a high voltage level may represent logic 1 while a low or zero voltage level may represent logic 0. The sense amplifier 101 may receive signals from a terminal sae 108 to turn on or turn off the sense amplifier 101.

In an exemplary embodiment of the invention, the sense amplifier 101 may comprise a first internal terminal, a second internal terminal, a third internal terminal and a fourth internal terminal. When the sense amplifier 101 is not enabled and turned off, the first internal terminal and the second internal terminal may be pre-charged to a high voltage level representing logic 1. The third internal terminal and the fourth internal terminal may be pre-charged to a low voltage level representing logic 0.

In operation, the bitlines 105, 106 are pre-charged to a high voltage level representing logic 1 prior to a selection of a memory cell such as the memory cell 103a. When the memory cell 103a is read-selected via the word line 107a, the memory cell 103 may put data on the bitlines 105, 106 and may generate a small voltage swing or voltage deviation between the terminals sbit 116 and sbitb 115.

In an exemplary embodiment of the invention, the sense amplifier 101 may be turned on, for example, via a sense enable signal at the terminal sae 108. When the sense amplifier 101 is turned on and receives differential input signals at the terminals sbit 116, sbitb 115, the sense amplifier 101 may be operable to form a first current-mirror reference using a first PMOS transistor and a NMOS transistor. In this regard, the first PMOS transistor may be a diode-connected transistor where a gate terminal of the first PMOS transistor may be coupled to a drain terminal of the first PMOS transistor. A drain terminal of the NMOS transistor may be coupled to the drain terminal of the first PMOS transistor. A gate terminal of the NMOS transistor may receive the sense enable signal from the terminal sae 108. A current at the first internal terminal and a current at the second internal terminal may be generated by the sense amplifier 101 based on the first current-mirror reference.

A voltage signal at the first internal terminal and a voltage signal at the second internal terminal may be generated by the sense amplifier 101 based on the received differential input signals at the terminals sbit 116, sbitb 115, the current at the first internal terminal, and the current at the second internal terminal. The sense amplifier 101 may be operable to limit voltage excursions of the voltage signal at the first internal terminal and/or of the voltage signal at the second internal terminal using a second PMOS transistor and a third PMOS transistor, respectively. In this regard, a gate terminal of the second PMOS transistor may be coupled to the second internal terminal. A drain terminal of the second PMOS transistor may be coupled to the first internal terminal. A gate terminal of the third PMOS transistor may be coupled to the first internal terminal. A drain terminal of the third PMOS transistor may be coupled to the second internal terminal.

A voltage signal at the third internal terminal and a voltage signal at the fourth internal terminal may be generated by the sense amplifier 101 based on the voltage signal at the first internal terminal, a current at the third internal terminal, the voltage signal at the second internal terminal and a current at the fourth internal terminal. In this regard, the current at the third internal terminal is a second current-mirror reference and the current at the fourth internal terminal may be generated based on the second current-mirror reference.

The sense amplifier 101 may be operable to generate an output signal at the output terminal doutn 109 of the sense amplifier 101 based on the voltage signal at the fourth internal terminal. When the output signal is generated and the sense amplifier 101 is turned off via the sense enable signal at the terminal sae 108, the sense amplifier 101 may be operable to hold the output signal at the output terminal doutn 109 at current voltage or logic level using a latch circuit in the sense amplifier 101. The latch circuit may comprise an inverter and a first tri-state inverter. In this regard, the inverter and the first tri-state inverter may be back-to-back connected and the output terminal doutn 109 may be coupled to an input terminal of the inverter. The first tri-state inverter may be controlled by the sense amplifier 101 using the sense enable signal received from the terminal sae 108.

In an exemplary embodiment of the invention, the sense amplifier 101 may be operable to generate the output signal at the output terminal doutn 109 of the sense amplifier 101 via a second tri-state inverter between the fourth internal terminal and the output terminal doutn 109. In this regard, the voltage signal at the fourth internal terminal is an input signal of the second tri-state inverter. The second tri-state inverter may be controlled by the sense amplifier 101 using the sense enable signal received from the terminal sae 108.

When the sense amplifier 101 is turned off via the sense enable signal received from the terminal sae 108, the first internal terminal may be pre-charged to a high voltage level by the sense amplifier 101. The second internal terminal may also be pre-charged to a high voltage level. The third internal terminal may be pre-charged to a low voltage level by the sense amplifier 101. The fourth internal terminal may also be pre-charged to a low voltage level.

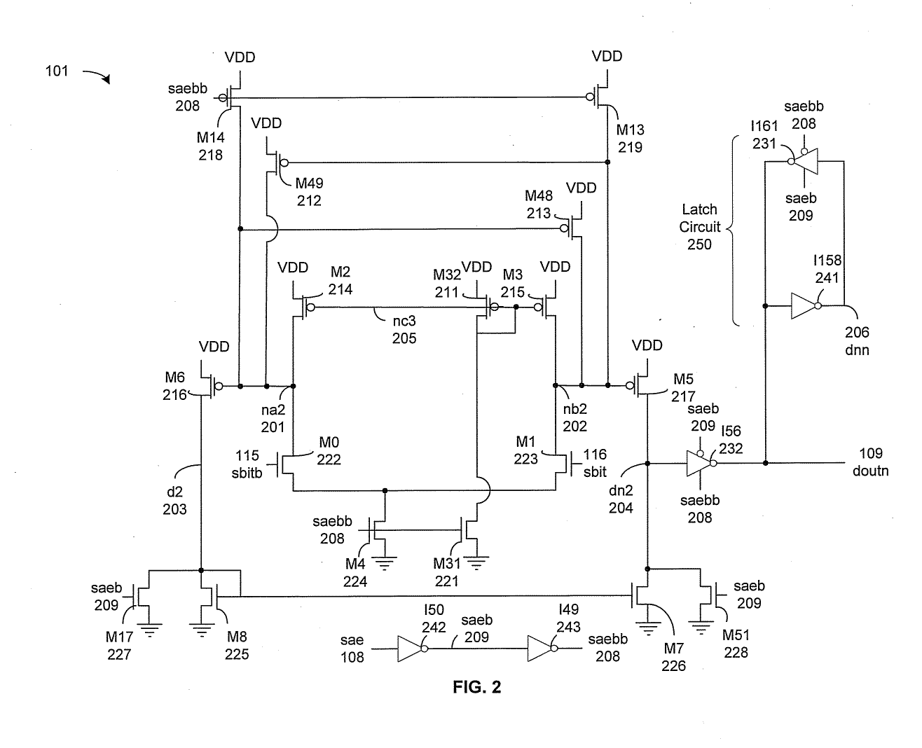

FIG. 2 is a schematic diagram illustrating an exemplary high speed differential synchronous sense amplifier, in accordance with an embodiment of the invention. Referring to FIG. 2, there is shown a high speed differential synchronous sense amplifier 101. The sense amplifier 101 may comprise PMOS transistors M32 211, M49 212, M48 213, M2 214, M3 215, M6 216, M5 217, M14 218, M13 219; NMOS transistors M31 221, M0 222, M1 223, M4 224, M8 225, M7 226, M17 227, M51 228; inverters I158 241, I50 242, I49 243 and tri-state inverters I161 231, I56 232.

The NMOS transistors M0 222 and M1 223 are configured in a differential input pair arrangement, which receive differential input signals at terminals sbitb 115 and sbit 116, respectively. The terminals sbitb 115, sbit 116 are pre-charged to a high voltage level before the sense amplifier 101 is turned on. The two inverters I50 242 and I49 243, which are serially coupled, make up a sense-amplifier-enable (SAE) buffer path. The inverter I50 242 may receive a sense enable signal at a terminal sae 108 and generate an inverted version of the sense enable signal at a terminal saeb 209. The inverter I49 243 may generate a buffered version of the sense enable signal at a terminal saebb 208.

The NMOS transistor M4 is the amplifier current source which may receive the sense enable signal via the terminal saebb 208. The NMOS transistor M31 221 and the PMOS transistor M32 211 may form a first current-mirror reference for a current at an internal terminal na2 201 and a current at an internal terminal nb2 202. In this regard, the NMOS transistor M31 221 is another current source. The PMOS transistor M32 211 is a diode-connected transistor where a gate terminal of the PMOS transistor M32 211 is coupled to a drain terminal of the PMOS transistor M32 211. The PMOS transistors M2 214 and M3 215 are current-mirror pull-up loads for the NMOS transistors M0 222 and M1 223 respectively. With this first current-mirror reference formed by the PMOS transistor M32 211 and the NMOS transistor M31 221 for the current at the internal terminal na2 201 and the current at the internal terminal nb2 202, the internal terminal na2 201 and the internal terminal nb2 202 may change voltage levels or states independently and may speed up turn-on responses of the PMOS transistors M6 216 and M5 217.

The PMOS transistor M6 216 and the NMOS transistor M8 225 may form a second current-mirror reference at an internal terminal d2 203 for a current at an internal terminal dn2 204. In this regard, the NMOS transistor M8 225 is a diode-connected transistor where a gate terminal of the NMOS transistor M8 225 is coupled to a drain terminal of the NMOS transistor M8 225. This second current-mirror reference is dependent upon a voltage level or a state at the internal terminal na2 201. Based on a high or a low voltage level at the internal terminal na2 201, the current of this second current-mirror reference may be different. Accordingly, the PMOS transistor M5 217 and the NMOS transistor M7 226 may generate a current-mirror controlled voltage signal at the internal terminal dn2 204. The voltage signal at the internal terminal dn2 204 may drive the tri-state inverter I56 232 to generate an output signal at an output terminal doutn 109 of the sense amplifier 101. The tri-state inverter I56 232 may be controlled by the sense enable signal via the terminal saeb 209 and the terminal saebb 208.

The cross coupled PMOS transistors M49 212 and M48 213 are operable to clamp or limit voltage excursions on the internal terminals na2 201 and nb2 202. A gate terminal of the PMOS transistor M49 212 may be coupled to the internal terminal nb2 202 and a drain terminal of the PMOS transistor M49 212 may be coupled to the internal terminal na2 201. A gate terminal of the PMOS transistor M48 213 may be coupled to the internal terminal na2 201 and a drain terminal of the PMOS transistor M48 213 may be coupled to the internal terminal nb2 202. The existence of the current-mirror reference transistors M32 211 and M31 221 may prevent the clamp transistors M49 212, M48 213 and the pull-up load transistors M2 214, M3 215 to form an unwanted positive feedback loop. The clamp transistors M49 212 and M48 213 may prevent voltage signals at the internal terminals na2 201, nb2 202 from exceeding threshold voltages of the PMOS transistors M6 216, M5 217 respectively at a started initial condition of a read operation so as to achieve a high performance propagation delay. In instances when the voltage signals at the internal terminals na2 201, nb2 202 exceed threshold voltages of the PMOS transistors M6 216, M5 217 respectively, the PMOS transistors M6 216 and/or the PMOS transistors M5 217 may be turned on. Accordingly, an unwanted glitch or an undesired transition may occur at the output terminal doutn 109 during a read-high operation and/or a transition at the output terminal doutn 109 may be slowed down during a read-low operation.

The PMOS transistor M14 218 may pre-charge or reset the internal terminal na2 201 to a high voltage level at an end of each sense cycle, making ready for the next data acquisition. Similarly, the PMOS transistor M13 219 may pre-charge or reset the internal terminal nb2 202 to a high voltage level at an end of each sense cycle. The NMOS transistor M17 227 may pre-charge or reset the internal terminal d2 203 to a low voltage level at an end of each sense cycle. The NMOS transistor M51 228 may pre-charge or reset the internal terminal dn2 204 to a low voltage level at an end of each sense cycle. Accordingly, the sense amplifier 101 may be reset to a known state or condition at an end of each sense cycle. Therefore, at a beginning of a memory access, the terminals sbitb 115, sbit 116 may start from a known high voltage level or state and the sense amplifier 101 may also start from a known state or condition. In this regard, for example, the internal terminal dn2 204 may start from a low voltage level representing logic 0.

The tri-state inverter I161 231 and the inverter I158 241 may form a latch circuit 250. The latch circuit 250 may perform a latch function which may retain captured memory bit information when the sense amplifier 101 is turned off via the sense enable signal. The tri-state inverter I161 231 and the inverter I158 241 may be back-to-back connected and the output terminal doutn 109 may be coupled to an input terminal of the inverter I158 241. The tri-state inverter I161 231 may be controlled by the sense enable signal via the terminal saeb 209 and the terminal saebb 208. When the tri-state inverter I56 232 is turned on via the sense enable signal, the tri-state inverter I161 231 is turned off via the sense enable signal. The output terminal doutn 109 is driven directly by the tri-state inverter I 56 232 with no delay and the output signal is latched in the latch circuit 250. When the tri-state inverter I56 232 is turned off, the tri-state inverter I161 231 is turned on. The output terminal doutn 109 is held at a current voltage level or state by the latch circuit 250. In this regard, the latch circuit 250 is off-to-the-side and not in a data path so as to maximize performance.

In operation, as the terminals sbitb 115 and sbit 116 are equally at a high voltage level VDD at the started initial condition, the matched NMOS transistors M0 222 and M1 223 may equally share a current-source current of the NMOS transistor M4 224. The matched current-mirror load transistors M2 214, M3 215 may each conduct those same currents and may translate those currents into common voltage levels, for example, in the range of VDD/2, on the internal terminals na2 201, nb2 202. As the terminals sbitb 115 and sbit 116 begin to separate in voltage level such as, for example, one of the terminals sbitb 115, sbit 116 begins to fall in voltage level, one of the NMOS transistors M0 222 and M1 223 may take more of the current-source current from the NMOS transistor M4 224 while the other may take less. The side which takes more current may have the corresponding internal terminal na2 201 or nb2 202 fall further in voltage level, while the other side which takes less current may begin to rise in voltage level, ultimately being restored to the high voltage level VDD. In this regard, for example, as the terminals sbitb 115 begins to fall in voltage level, the NMOS transistor M1 223 may take more of the current-source current from the NMOS transistor M4 224 while the NMOS transistor M0 222 may take less. This may have the internal terminal nb2 202 fall further in voltage level, while the internal terminal na2 201 may begin to rise in voltage level, ultimately being restored to the high voltage level VDD. A similar scenario may occur in the case where the terminal sbit 116 falls, repeating the process in the other direction.

For the case that the terminal sbitb 115 falls in voltage level, a resulting clean low-to-high transition may occur at the internal terminal dn2 204. However, for the case that the terminal sbit 116 falls in voltage level, a positive going glitch may occur at the internal terminal dn2 204, although the internal terminal dn2 204 is intended to remain at a low voltage level representing logic 0. In an exemplary embodiment of the invention, this positive glitch at the internal terminal dn2 204 may be small and seemingly insignificant and may not affect a high-going transition at the output terminal doutn 109 as long as the voltage signal at the internal terminal nb2 202 does not exceed the threshold voltage of the PMOS transistor M5 217. In instances when the voltage signal at the internal terminal nb2 202 exceeds the threshold voltage of the PMOS transistor M5 217, the PMOS transistor M5 217 may be turned on and this positive going glitch may become higher and/or wider. Accordingly, an unwanted glitch or an undesired transition may occur at the output terminal doutn 109.

Until there is sufficient separation on the terminals sbitb 115 and sbit 116, both the internal terminals na2 201 and nb2 202 may fall in voltage level toward the range of VDD/2 in unison. As the internal terminals na2 201 and nb2 202 both fall in voltage level and reach the threshold voltages of the PMOS transistors M49 212 and M48 213, the PMOS transistor M49 212 and M48 213 may begin to turn on. As one of the NMOS transistors M0 222, M1 223 starts to take more of the current-source current from the NMOS transistor M4 224, the corresponding internal terminal na2 201 or nb2 202 may continue to fall in voltage level. Accordingly, one of the PMOS transistors M49 212, M48 213 may turn on harder and have more drive to pull up the opposite side. This may in turn cause the other PMOS transistor, M49 212 or M48 213 to shut off and limit it's clamping action, thus allowing that side to continue to fall in voltage level. In this regard, for example, as the NMOS transistor M0 222 starts to take more of the current-source current from the NMOS transistor M4 224, the internal terminal na2 201 may continue to fall in voltage level. Accordingly, the PMOS transistor M48 213 may turn on harder and have more drive to pull up the internal terminal nb2 202. This may in turn cause the PMOS transistor M49 212 to shut off and limit its clamping action, thus allowing the internal terminal na2 201 to continue to fall in voltage level. In this instance, the PMOS transistors M49 212, M48 213 may not only clamp or limit the voltage level from falling too low on the internal terminal nb2 202, they may also recover the voltage level on the internal terminal nb2 202 quickly to get back to the stable high voltage level VDD.

In an exemplary read-low operation, the output terminal doutn 109 may start at a high voltage level representing logic 1 as that might be the latched state from a previous cycle. The internal terminal dn2 204 may be pre-charged or preset to a low voltage level. The terminal sbitb 115 may fall in voltage level and begin to create a bitline separation. As soon as the sense enable signal at the terminal sae 108 changes from a low voltage level to a high voltage level, a delayed version of the sense enable signal may be generated at the terminal saebb 208. Initially, the NMOS transistors M0 222 and M1 223 may share the current-source current from the NMOS transistor M4 224, and the internal terminals na2 201 and nb2 202 may fall in voltage level in unison. As the bitline separation increases, the NMOS transistor M1 223 may take a majority of the current-source current while the NMOS transistor M0 222 may get less and less of the current-source current. The internal terminal nb2 202 may continue to fall in voltage level while the internal terminal na2 201 may stop falling in voltage level and may begin to rise without exceeding the threshold voltage of the PMOS transistor M6 216. As the PMOS transistor M6 216 may remain off, little or no current may be available for the current-mirror transistor pair M8 225 and M7 226. As the internal terminal nb2 202 continues to fall in voltage level and may exceed the threshold voltage of the PMOS transistor M5 217, the PMOS transistor M5 217 may be turned on and may pull the internal terminal dn2 204 from the preset low voltage level to a high voltage level unimpeded by the NMOS transistor M7 226. The tri-state inverter I56 232 may be enabled by the sense enable signal via the terminals saebb 208, saeb 209 and may sense it's input transition at the internal terminal dn2 204. The tri-state inverter I56 232 may drive the output terminal doutn 109 from the high voltage level representing logic 1 to a low voltage level representing logic 0.

As the sense enable signal at the terminal sae 108 changes from the high voltage level to a low voltage level, the latch circuit 250 which comprises the tri-state inverter I161 231 and the inverter I158 241 may latch the low voltage level or state of the output terminal doutn 109. The internal terminal dn2 204 may be pre-charged or reset to a low voltage level representing logic 0 as the NMOS transistor M51 228 may be activated by a high voltage signal at the terminal saeb 209.

In an exemplary read-high operation, the output terminal doutn 109 may start at a low voltage level representing logic 0 as that might be the latched state from a previous cycle. The internal terminal dn2 204 may be pre-charged or preset to a low voltage level. The terminal sbit 116 may fall in voltage level and begin to create a bitline separation. As soon as the sense enable signal at the terminal sae 108 changes from a low voltage to a high voltage level, a delayed version of the sense enable signal may be generated at the terminal saebb 208. The tri-state inverter I56 232 may be enabled by the sense enable signal via the terminals saebb 208, seab 209 and may sense it's low voltage level input at internal terminal dn2 204. The tri-state inverter I56 232 may immediately drive the output terminal doutn 109 from the low level to a high voltage level representing logic 1. Initially, the NMOS transistors M0 222 and M1 223 may share the current-source current from the NMOS transistor M4 224, and the internal terminals na2 201 and nb2 202 may fall in voltage level in unison. As the bitline separation increases, the NMOS transistor M0 222 may take a majority of the current-source current while the NMOS transistor M1 223 may get less and less of the current-source current. The internal terminal na2 201 may continue to fall in voltage level and may exceed the threshold voltage of the transistor M6 216 while the internal terminal nb2 202 may stop falling and may begin to rise without exceeding the threshold voltage of the PMOS transistor M5 217.

The PMOS transistor M6 216 may be turned on and may supply current into the current-mirror transistor M8 225 which will be matched by the transistor M7 226. As the PMOS transistor M5 217 may remain off, little or no current may fight the current in the NMOS transistor M7 226 and the internal terminal dn2 204 may be driven to a low voltage and may remain at it's original preset low voltage level representing logic 0. Still the enabled tri-state inverter I56 232, sensing no input transition, may continue to drive the output terminal doutn 109 at the high voltage level representing logic 1.

As the sense enable signal at the terminal sae 108 changes from the high voltage level representing logic 1 to a low voltage level representing logic 0, the latch circuit 250 which comprises the tri-state inverter I161 231 and the inverter I158 241 may latch the high voltage level or state of the output terminal doutn 109. The internal terminal dn2 204 may be pre-charged or reset to a low voltage level representing logic 0 as the NMOS transistor M51 228 may be activated by a high voltage signal at the terminal saeb 209.

In an exemplary embodiment of the invention, during a design stage of the sense amplifier 101, a P/N ratio of each of the inverters I50 242, I49 243 may be adjusted to skew trip points of the inverter I50 242 and/or the inverter I49 243. Skewing the trip points of the inverter I50 242 and/or the inverter I49 243 may enable an ability to tradeoff a delay of an important rising edge verses a non-timing critical falling edge of the sense enable signal. In addition, skewing the trip points of the inverter I50 242 and/or the inverter I49 243 may enable a tradeoff between a SAE buffer delay and a size of the glitch at the internal terminal nd2 204. The glitch at the internal terminal nd2 204 may occur at the started initial condition during the read-high operation. By slowing down the buffer delay, the unwanted glitch at the internal terminal dn2 204 may be reduced. In instances when the glitch is already tolerable, the buffer may be sped up to maximize SAE delay performance.

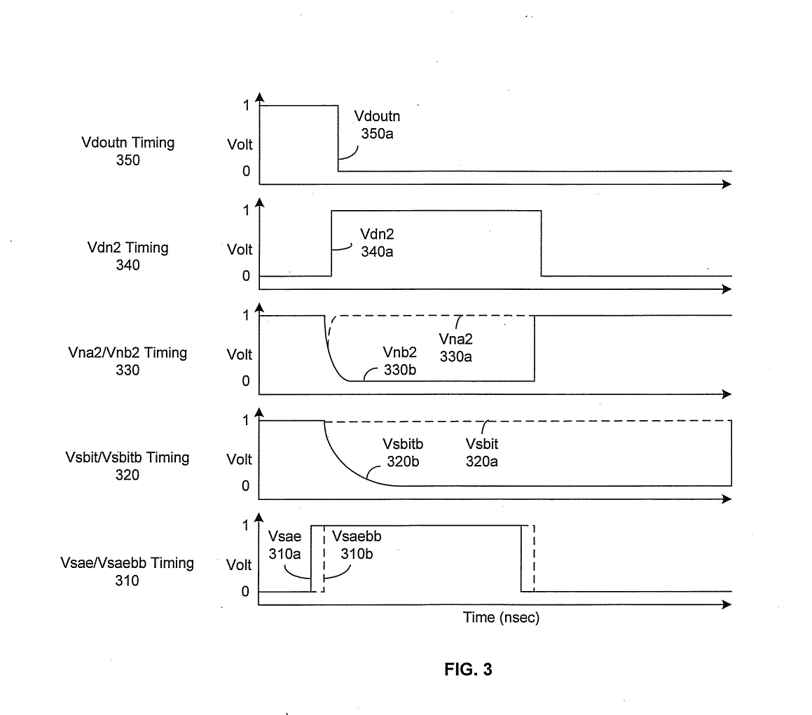

FIG. 3 is a timing diagram illustrating an exemplary read-low operation of a high speed differential synchronous sense amplifier, in accordance with an embodiment of the invention. Referring to FIG. 3, there is shown a Vsae/Vsaebb timing chart 310, a Vsbit/Vsbitb timing chart 320, a Vna2/Vnb2 timing chart 330, a Vdn2 timing chart 340 and a Vdoutn timing chart 350. The Vsae/Vsaebb timing chart 310 may comprise a voltage signal Vsae 310a at the terminal sae 108 and a voltage signal Vsaebb 310b at the terminal saebb 208. The Vsbit/Vsbitb timing chart 320 may comprise a voltage signal Vsbit 320a at the terminal sbit 116 and a voltage signal Vsbitb 320b at the terminal sbitb 115. The Vna2/Vnb2 timing chart 330 may comprise a voltage signal Vna2 330a at the internal terminal na2 201 and a voltage signal Vnb2 330b at the internal terminal nb2 202. The Vdn2 timing chart 340 may comprise a voltage signal Vdn2 340a at the internal terminal dn2 204. The Vdoutn timing chart 350 may comprise an output signal Vdoutn 350a at the output terminal doutn 109.

In an exemplary read-low operation, the output terminal doutn 109 may start at a high voltage level representing logic 1 as illustrated by the output signal Vdoutn 350a in the Vdoutn timing chart 350. The internal terminal dn2 204 may be pre-charged or preset to a low voltage level representing logic 0 as illustrated by the voltage signal Vdn2 340a in the Vdn2 timing chart 340. The terminal sbitb 115 may fall in voltage level and begin to create a bitline separation as illustrated by the voltage signal Vsibitb 320b in the Vsbit/Vsbitb timing chart 320. As soon as the sense enable signal at the terminal sae 108 changes from a low voltage level to a high voltage level, a delayed version of the sense enable signal may be generated at the terminal saebb 208 as illustrated by the voltage signal Vsae 310a and the voltage signal Vsaebb 310b in the Vsae/Vsaebb timing chart 310. Initially, the NMOS transistors M0 222 and M1 223 may share the current-source current from the NMOS transistor M4 224, and the internal terminals na2 201 and nb2 202 may fall in voltage level in unison as illustrated by the voltage signal Vna2 330a and the voltage signal Vnb2 330b in the Vna2/Vnb2 timing chart 330. As the bitline separation increases, the NMOS transistor M1 223 may take a majority of the current-source current while the NMOS transistor M0 222 may get less and less of the current-source current. The internal terminal nb2 202 may continue to fall in voltage level while the internal terminal na2 201 may stop falling in voltage level and may begin to rise without exceeding the threshold voltage of the PMOS transistor M6 216. This scenario may be illustrated by the voltage signal Vna2 330a and the voltage signal Vnb2 330b in the Vna2/Vnb2 timing chart 330.

As the PMOS transistor M6 216 may remain off, little or no current may be available for the current-mirror transistor pair M8 225 and M7 226. As the internal terminal nb2 202 continues to fall in voltage level and may exceed the threshold voltage of the PMOS transistor M5 217, the PMOS transistor M5 217 may be turned on and may pull the internal terminal dn2 204 from the preset low voltage level to a high voltage level unimpeded by the NMOS transistor M7 226. This scenario may be illustrated by the voltage signal Vdn2 340a in the Vdn2 timing chart 340. The tri-state inverter I56 232 may be enabled by the sense enable signal via the terminals saebb 208, saeb 209 and may sense it's input transition at the internal terminal dn2 204. The tri-state inverter I56 232 may drive the output terminal doutn 109 from the high voltage level to a low voltage level, as illustrated by the output signal Vdoutn 350a in the Vdoutn timing chart 350.

As the sense enable signal at the terminal sae 108 changes from the high voltage level to a low voltage level, the latch circuit 250 may latch the low voltage level or state of the output terminal doutn 109 as illustrated by the output signal Vdoutn 350a in the Vdoutn timing chart 350. The internal terminal dn2 204 may be pre-charged or reset to a low voltage level as the NMOS transistor M51 228 may be activated by a high voltage signal at the terminal saeb 209. This scenario may be illustrated by the voltage signal Vdn2 340a in the Vdn2 timing chart 340. The internal terminal na2 201 may be pre-charged or reset to a high voltage level as the PMOS transistor M14 218 may be activated by a low voltage signal at the terminal saebb 208. The internal terminal nb2 202 may be pre-charged or reset to a high voltage level as the PMOS transistor M13 219 may be activated by a low voltage signal at the terminal saebb 208. These scenarios may be illustrated by the voltage signals Vna2 330a, Vnb2 330b in the Vna2/Vnb2 timing chart 330.

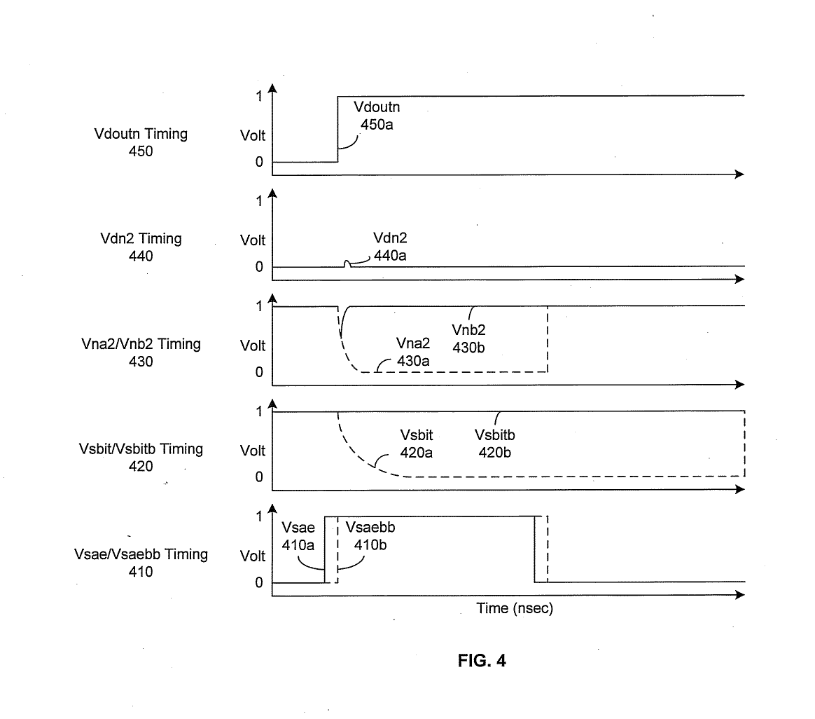

FIG. 4 is a timing diagram illustrating an exemplary read-high operation of a high speed differential synchronous sense amplifier, in accordance with an embodiment of the invention. Referring to FIG. 4, there is shown a Vsae/Vsaebb timing chart 410, a Vsbit/Vsbitb timing chart 420, a Vna2/Vnb2 timing chart 430, a Vdn2 timing chart 440 and a Vdoutn timing chart 450. The Vsae/Vsaebb timing chart 410 may comprise a voltage signal Vsae 410a at the terminal sae 108 and a voltage signal Vsaebb 410b at the terminal saebb 208. The Vsbit/Vsbitb timing chart 420 may comprise a voltage signal Vsbit 420a at the terminal sbit 116 and a voltage signal Vsbitb 420b at the terminal sbitb 115. The Vna2/Vnb2 timing chart 430 may comprise a voltage signal Vna2 430a at the internal terminal na2 201 and a voltage signal Vnb2 430b at the internal terminal nb2 202. The Vdn2 timing chart 440 may comprise a voltage signal Vdn2 440a at the internal terminal dn2 204. The Vdoutn timing chart 450 may comprise an output signal Vdoutn 450a at the output terminal doutn 109.

In an exemplary read-high operation, the output terminal doutn 109 may start at a low voltage level representing logic 0 as illustrated by the output signal Vdoutn 450a in the Vdoutn timing chart 450. The internal terminal dn2 204 may be pre-charged or preset to a low voltage level representing logic 0 as illustrated by the voltage signal Vdn2 440a in the Vdn2 timing chart 440. The terminal sbit 116 may fall in voltage level and begin to create a bitline separation as illustrated by the voltage signal Vsbit 420a in the Vsbit/Vsbitb timing chart 420. As soon as the sense enable signal at the terminal sae 108 changes from a low voltage level to a high voltage level, a delayed version of the sense enable signal may be generated at the terminal saebb 208 as illustrated by the voltage signal Vsae 410a and the voltage signal Vsaebb 410b in the Vsae/Vsaebb timing chart 410. The tri-state inverter I56 232 may be enabled by the sense enable signal via the terminals saebb 208, seab 209 and may sense it's low voltage level input at internal terminal dn2 204. The tri-state inverter I56 232 may drive immediately the output terminal doutn 109 from the low voltage level representing logic 0 to a high voltage level representing logic 1 as illustrated by the output signal Vdoutn 450a in the Vdoutn timing chart 450. Initially, the NMOS transistors M0 222 and M1 223 may share the current-source current from the NMOS transistor M4 224, and the internal terminals na2 201 and nb2 202 may fall in voltage level in unison as illustrated by the voltage signal Vna2 430a and the voltage signal Vnb2 430b in the Vna2/Vnb2 timing chart 430.

As the bitline separation increases, the NMOS transistor M0 222 may take a majority of the current-source current while the NMOS transistor M1 223 may get less and less of the current-source current. The internal terminal na2 201 may continue to fall in voltage level and may exceed the threshold voltage of the transistor M6 216 while the internal terminal nb2 202 may stop falling and may begin to rise without exceeding the threshold voltage of the PMOS transistor M5 217. This scenario may be illustrated by the voltage signal Vna2 430a and the voltage signal Vnb2 430b in the Vna2/Vnb2 timing chart 430.

As illustrated by the voltage signal Vdn2 440a in the Vdn2 timing chart 440, a positive glitch may occur at the internal terminal dn2 204, although the internal terminal dn2 204 is intended to remain at a low voltage level. As long as the voltage signal at the internal terminal nb2 202 does not exceed the threshold voltage of the PMOS transistor M5 217, the positive glitch at the internal terminal dn2 204 may be small and seemingly insignificant and may not affect a high-going transition at the output terminal doutn 109, as illustrated by the output signal Vdoutn 450a in the Vdoutn timing chart 450. The PMOS transistor M6 216 may be turned on and may supply current into the current-mirror transistor M8 225 which will be matched by the transistor M7 226. As the PMOS transistor M5 217 may remain off, little or no current may fight the current in the NMOS transistor M7 226 and the internal terminal dn2 204 may be driven to a low voltage and may remain at it's original preset low voltage level, as illustrated by the voltage signal Vdn2 440a in the Vdn2 timing chart 440. The enabled tri-state inverter I56 232, sensing no input transition, may continue to drive the output terminal doutn 109 at the high voltage level representing logic 1 as illustrated by the output signal Vdoutn 450a in the Vdoutn timing chart 450.

As the sense enable signal at the terminal sae 108 changes from the high voltage level to a low voltage level, the latch circuit 250 may latch the high voltage level or state of the output terminal doutn 109 as illustrated by the output signal Vdoutn 450a in the Vdoutn timing chart 450. The internal terminal dn2 204 may be pre-charged or reset to a low voltage level representing logic 0 as the NMOS transistor M51 228 may be activated by a high voltage signal at the terminal saeb 209. This scenario may be illustrated by the voltage signal Vdn2 440a in the Vdn2 timing chart 440. The internal terminal na2 201 may be pre-charged or reset to a high voltage level representing logic 1 as the PMOS transistor M14 218 may be activated by a low voltage signal at the terminal saebb 208. The internal terminal nb2 202 may be pre-charged or reset to a high voltage level representing logic 1 as the PMOS transistor M13 219 may be activated by a low voltage signal at the terminal saebb 208. These scenarios may be illustrated by the voltage signals Vna2 430a, Vnb2 430b in the Vna2/Vnb2 timing chart 430.

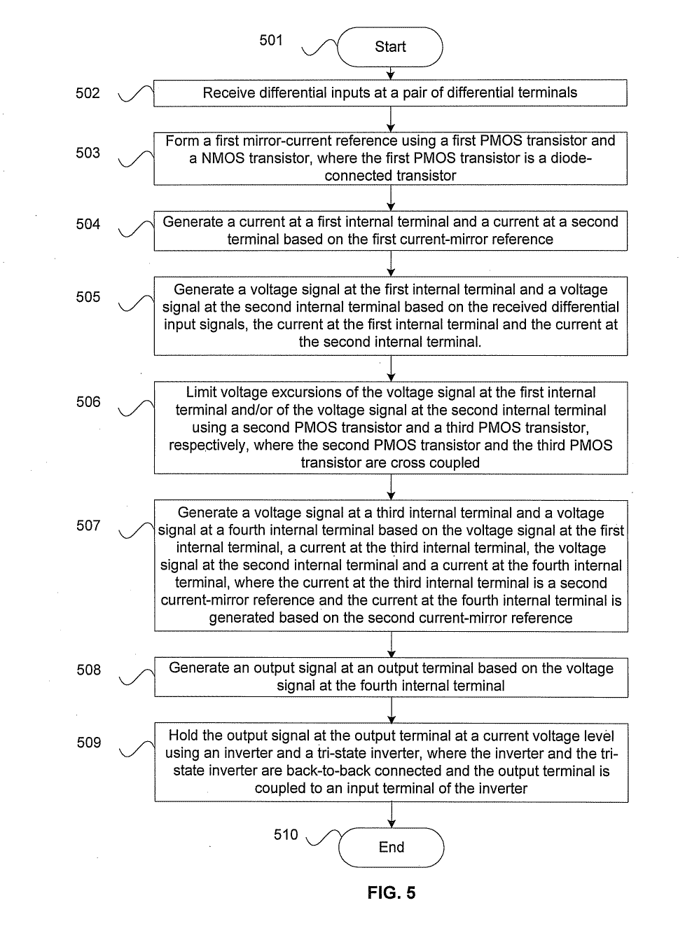

FIG. 5 is a flow chart illustrating exemplary steps for a high speed differential synchronous sense amplifier, in accordance with an embodiment of the invention. Referring to FIG. 5, the exemplary steps start at step 501. In step 502, when the sense amplifier 101 is turned on, the sense amplifier 101 may be operable to receive differential input signals at a pair of differential terminals sbit 116, sbitb 115. In step 503, the sense amplifier 101 may be operable to form a first current-mirror reference using a first PMOS transistor M32 211 and a NMOS transistor M31 221. In this regard, the first PMOS transistor M32 211 may be a diode-connected transistor where a gate terminal of the first PMOS transistor M32 211 may be coupled to a drain terminal of the first PMOS transistor M32 211. A drain terminal of the NMOS transistor M31 221 may be coupled to the drain terminal of the first PMOS transistor M32 211. A gate terminal of the NMOS transistor M31 221 may receive the sense enable signal via the terminal saebb 208. In step 504, a current at a first internal terminal na2 201 and a current at a second internal terminal nb2 202 may be generated by the sense amplifier 101 based on the first current-mirror reference. In step 505, a voltage signal at the first internal terminal na2 201 and a voltage signal at the second internal terminal nb2 202 may be generated by the sense amplifier 101 based on the received differential input signals at the terminals sbit 116, sbitb 115, the current at the first internal terminal na2 201, and the current at the second internal terminal nb2 202.

In step 506, the sense amplifier 101 may be operable to limit voltage excursions of the voltage signal at the first internal terminal na2 201 and/or of the voltage signal at the second internal terminal nb2 202 using a second PMOS transistor M49 212 and a third PMOS transistor M48 213, respectively. In this regard, the second PMOS transistor M49 212 and the third PMOS transistor M48 213 may be cross coupled. A gate terminal of the second PMOS transistor M49 212 may be coupled to the second internal terminal nb2 202. A drain terminal of the second PMOS transistor M49 212 may be coupled to the first internal terminal na2 201. A gate terminal of the third PMOS transistor M48 213 may be coupled to the first internal terminal na2 201. A drain terminal of the third PMOS transistor M48 213 may be coupled to the second internal terminal nb2 202.

In step 507, a voltage signal at a third internal terminal d2 203 and a voltage signal at a fourth internal terminal dn2 204 may be generated by the sense amplifier 101 based on the voltage signal at the first internal terminal na2 201, a current at the third internal terminal d2 203, the voltage signal at the second internal terminal nb2 202 and a current at the fourth internal terminal dn2 204. In this regard, the current at the third internal terminal d2 203 is a second current-mirror reference and the current at the fourth internal terminal dn2 204 may be generated based on the second current-mirror reference. In step 508, the sense amplifier 101 may be operable to generate an output signal at an output terminal doutn 109 based on the voltage signal at the fourth internal terminal dn2 204. In step 509, when the output signal is generated and the sense amplifier 101 is turned off via the sense enable signal, the sense amplifier 101 may be operable to hold the output signal at the output terminal doutn 109 at a current voltage or logic level using an inverter I158 241 and a tri-state inverter I161 231. In this regard, the inverter I158 241 and the tri-state inverter I161 231 may be back-to-back connected and the output terminal doutn 109 may be coupled to an input terminal of the inverter I158 241. The exemplary steps may proceed to the end step 510.

In various embodiments of the invention, a sense amplifier 101 may comprise a first internal terminal na2 201, a second internal terminal nb2 202, a third internal terminal d2 203, a fourth internal terminal dn2 204, a first PMOS transistor M32 211, a second PMOS transistor M49 212, a third PMOS transistor M48 213 and a NMOS transistor M31 221. When the sense amplifier 101 is turned on and receives differential input signals at a pair of differential input terminals sbit 116, sbitb 115, the sense amplifier 101 may be operable to form a first current-mirror reference using the first PMOS transistor M32 211 and the NMOS transistor M31 221. In this regard, a gate terminal of the first PMOS transistor M32 211 may be coupled to a drain terminal of the first PMOS transistor M32 211. A drain terminal of the NMOS transistor M31 221 may be coupled to the drain terminal of the first PMOS transistor M32 211. A gate terminal of the NMOS transistor M31 221 may receive a sense enable signal that may enable the turning on of the sense amplifier 101. The sense enable signal may be received from a terminal sae 108. A current at the first internal terminal na2 201 and a current at the second internal terminal nb2 202 may be generated by the sense amplifier 101 based on the first current-mirror reference.

A voltage signal at the first internal terminal na2 201 and a voltage signal at the second internal terminal nb2 202 may be generated by the sense amplifier 101 based on the received differential input signals, the current at the first internal terminal na2 201 and the current at the second internal terminal nb2 202. The sense amplifier 101 may be operable to limit voltage excursions of the voltage signal at the first internal terminal na2 201 and/or of the voltage signal at the second internal terminal nb2 202 using the second PMOS transistor M49 212 and the third PMOS transistor M48 213, respectively. In this regard, the second PMOS transistor M49 212 and the third PMOS transistor M48 213 may be cross coupled. A gate terminal of the second PMOS transistor M49 212 may be coupled to the second internal terminal nb2 202. A drain terminal of the second PMOS transistor M49 212 may be coupled to the first internal terminal na2 201. A gate terminal of the third PMOS transistor M48 213 may be coupled to the first internal terminal na2 201. A drain terminal of the third PMOS transistor M48 213 may be coupled to the second internal terminal nb2 202.

A voltage signal at the third internal terminal d2 203 and a voltage signal at the fourth internal terminal dn2 204 may be generated by the sense amplifier 101 based on the voltage signal at the first internal terminal na2 201, a current at the third internal terminal d2 203, the voltage signal at the second internal terminal nb2 202 and a current at the fourth internal terminal dn2 204. In this regard, the current at the third internal terminal d2 203 is a second current-mirror reference and the current at the fourth internal terminal dn2 204 may be generated based on the second current-mirror reference.

The sense amplifier 101 may be operable to generate an output signal at an output terminal doutn 109 of the sense amplifier 101 based on the voltage signal at the fourth internal terminal dn2 204. When the sense amplifier 101 is turned off via the sense enable signal, the sense amplifier 101 may be operable to hold the output signal at the output terminal doutn 109 at a current voltage level using an inverter I158 241 and a first tri-state inverter I161 231. In this regard, the inverter I158 241 and the first tri-state inverter I161 231 may be back-to-back connected and the output terminal doutn 109 may be coupled to an input terminal of the inverter I158 241. The first tri-state inverter I161 231 may be controlled by the sense amplifier 101 using the buffered sense enable signal.

In an exemplary embodiment of the invention, the sense amplifier 101 may be operable to generate the output signal at the output terminal doutn 109 of the sense amplifier 101 via a second tri-state inverter I56 232 between the fourth internal terminal dn2 204 and the output terminal doutn 109. In this regard, the voltage signal at the fourth internal terminal dn2 204 is an input signal of the second tri-state inverter I56 232. The second tri-state inverter I56 232 may be controlled by the sense amplifier 101 using the buffered sense enable signal.

When the sense amplifier 101 is turned off via the sense enable signal, the first internal terminal na2 201 may be pre-charged to a high voltage level by the sense amplifier 101. The second internal terminal nb2 202 may also be pre-charged to a high voltage level. The third internal terminal d2 203 may be pre-charged to a low voltage level by the sense amplifier 101. The fourth internal terminal dn2 204 may also be pre-charged to a low voltage level.

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the steps as described herein for high speed differential synchronous sense amplifier.

Accordingly, the present invention may be realized in hardware, software, or a combination of hardware and software. The present invention may be realized in a centralized fashion in at least one computer system or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for sense amplifier circuitry, the method comprising:
in a sense amplifier comprising a first internal terminal, a second internal terminal, a third internal terminal, a fourth internal terminal, a first PMOS transistor, a second PMOS transistor, a third PMOS transistor and a NMOS transistor:
when said sense amplifier is turned on and receives differential input signals at a pair of differential input terminals, forming a first current-mirror reference using said first PMOS transistor and said NMOS transistor;
generating a current at said first internal terminal and a current at said second internal terminal based on said first current-mirror reference;
generating a voltage signal at said first internal terminal and a voltage signal at said second internal terminal based on said received differential input signals, said current at said first internal terminal and said current at said second internal terminal; and
limiting voltage excursions of said voltage signal at said first internal terminal and/or of said voltage signal at said second internal terminal using said second PMOS transistor and said third PMOS transistor, respectively, wherein said second PMOS transistor and said third PMOS transistor are cross coupled.

2. The method according to claim 1, wherein a gate terminal of said first PMOS transistor is coupled to a drain terminal of said first PMOS transistor, a drain terminal of said NMOS transistor is coupled to said drain terminal of said first PMOS transistor and a gate terminal of said NMOS transistor receives a sense enable signal that enables said turning on of said sense amplifier.

3. The method according to claim 1, wherein a gate terminal of said second PMOS transistor is coupled to said second internal terminal, a drain terminal of said second PMOS transistor is coupled to said first internal terminal, a gate terminal of said third PMOS transistor is coupled to said first internal terminal and a drain terminal of said third PMOS transistor is coupled to said second internal terminal.

4. The method according to claim 1, comprising generating a voltage signal at said third internal terminal and a voltage signal at said fourth internal terminal based on said voltage signal at said first internal terminal, a current at said third internal terminal, said voltage signal at said second internal terminal and a current at said fourth internal terminal, wherein said current at said third internal terminal is a second current-mirror reference and said current at said fourth internal terminal is generated based on said second current-mirror reference.

5. The method according to claim 4, comprising generating an output signal at an output terminal of said sense amplifier based on said voltage signal at said fourth internal terminal.

6. The method according to claim 5, comprising, when said sense amplifier is turned off via a sense enable signal that enables said turning on of said sense amplifier, holding said output signal at said output terminal at a current voltage level using an inverter and a first tri-state inverter, wherein said inverter and said first tri-state inverter are back-to-back connected, and said output terminal is coupled to an input terminal of said inverter.

7. The method according to claim 6, comprising controlling said first tri-state inverter using said sense enable signal.

8. The method according to claim 4, comprising generating an output signal at an output terminal of said sense amplifier via a second tri-state inverter between said fourth internal terminal and said output terminal, wherein said voltage signal at said fourth internal terminal is an input signal of said second tri-state inverter.

9. The method according to claim 8, comprising controlling said second tri-state inverter using a sense enable signal that enables said turning on of said sense amplifier.

10. The method according to claim 1, comprising, when said sense amplifier is turned off via a sense enable signal, which enables said turning on of said sense amplifier:
pre-charging said first internal terminal to a high voltage level;
pre-charging said second internal terminal to a high voltage level;
pre-charging said third internal terminal to a low voltage level; and
pre-charging said fourth internal terminal to a low voltage level.

11. A system for sense amplifier circuitry, the system comprising:
one or more circuits for use in a sense amplifier, said one or more circuits comprising a first internal terminal, a second internal terminal, a third internal terminal, a fourth internal terminal, a first PMOS transistor, a second PMOS transistor, a third PMOS transistor and a NMOS transistor, and said one or more circuits being operable to:
when said sense amplifier is turned on and receives differential input signals at a pair of differential input terminals, form a first current-mirror reference using said first PMOS transistor and said NMOS transistor;
generate a current at said first internal terminal and a current at said second internal terminal based on said first current-mirror reference;
generate a voltage signal at said first internal terminal and a voltage signal at said second internal terminal based on said received differential input signals, said current at said first internal terminal and said current at said second internal terminal; and
limit voltage excursions of said voltage signal at said first internal terminal and/or of said voltage signal at said second internal terminal using said second PMOS transistor and said third PMOS transistor, respectively, wherein said second PMOS transistor and said third PMOS transistor are cross coupled.

12. The system according to claim 11, wherein a gate terminal of said first PMOS transistor is coupled to a drain terminal of said first PMOS transistor, a drain terminal of said NMOS transistor is coupled to said drain terminal of said first PMOS transistor and a gate terminal of said NMOS transistor receives a sense enable signal that enables said turning on of said sense amplifier.

13. The system according to claim 11, wherein a gate terminal of said second PMOS transistor is coupled to said second internal terminal, a drain terminal of said second PMOS transistor is coupled to said first internal terminal, a gate terminal of said third PMOS transistor is coupled to said first internal terminal and a drain terminal of said third PMOS transistor is coupled to said second internal terminal.

14. The system according to claim 11, wherein said one or more circuits are operable to generate a voltage signal at said third internal terminal and a voltage signal at said fourth internal terminal based on said voltage signal at said first internal terminal, a current at said third internal terminal, said voltage signal at said second internal terminal and a current at said fourth internal terminal, said current at said third internal terminal is a second current-mirror reference and said current at said fourth internal terminal is generated based on said second current-mirror reference.

15. The system according to claim 14, wherein said one or more circuits are operable to generate an output signal at an output terminal of said sense amplifier based on said voltage signal at said fourth internal terminal.

16. The system according to claim 15, wherein, when said sense amplifier is turned off via a sense enable signal that enables said turning on of said sense amplifier, said one or more circuits are operable to hold said output signal at said output terminal at a current voltage level using an inverter and a first tri-state inverter, said inverter and said first tri-state inverter are back-to-back connected, and said output terminal is coupled to an input terminal of said inverter.

17. The system according to claim 16, wherein said one or more circuits are operable to control said first tri-state inverter using said sense enable signal.

18. The system according to claim 14, wherein said one or more circuits are operable to generate an output signal at an output terminal of said sense amplifier via a second tri-state inverter between said fourth internal terminal and said output terminal, and said voltage signal at said fourth internal terminal is an input signal of said second tri-state inverter.

19. The system according to claim 18, wherein said one or more circuits are operable to control said second tri-state inverter using a sense enable signal that enables said turning on of said sense amplifier.

20. The system according to claim 11, wherein, when said sense amplifier is turned off via a sense enable signal, which enables said turning on of said sense amplifier, said one or more circuits are operable to:
pre-charge said first internal terminal to a high voltage level;
pre-charge said second internal terminal to a high voltage level;
pre-charge said third internal terminal to a low voltage level; and
pre-charge said fourth internal terminal to a low voltage level.
